(19) United States
(12) Patent Application Publication
(10) Pub. No.: US 2014/0061786 A1
(43) Pub. Date: Mar. 6, 2014

(54) Double Diffused Metal Oxide Semiconductor Device and Manufacturing Method Thereof

(71) Applicants: Tsung-Yi Huang, Hsinchu City (TW); Chien-Wei Chiu, Beigang Township (TW)

(72) Inventors: Tsung-Yi Huang, Hsinchu City (TW); Chien-Wei Chiu, Beigang Township (TW)

(73) Assignee: Richtek Technology Corporation

(21) Appl. No.: 13/603,385

(22) Filed: Sep. 4, 2012

(51) Int. Cl. H01L 29/78; H01L 21/336

(52) U.S. Cl. 257/339; 438/286; 257/E29.256; 257/E21.417

(57) ABSTRACT

The present invention discloses a double diffused metal oxide semiconductor (DMOS) device and a manufacturing method thereof. The DMOS device includes a first conductive type substrate, a second conductive type high voltage well, a first conductive type deep buried region, a field oxide region, a first conductive type body region, a gate, a second conductive type source, and a second conductive type drain. The deep buried region is formed below the high voltage well with a gap in between, and the gap is not less than a predetermined distance.

### BACKGROUND OF THE INVENTION

1. Field of Invention

The present invention relates to a double diffused metal oxide semiconductor (DMOS) device and a manufacturing method thereof; particularly, it relates to such DMOS device and a manufacturing method thereof wherein the breakdown voltage is increased.

2. Description of Related Art

FIGS. 1A and 1B show a cross-section view and a 3D (3-dimensional) view of a prior art double diffused metal oxide semiconductor (DMOS) device 100, respectively. As shown in FIGS. 1A-1B, a P-type substrate 11 has multiple isolation regions 12 by which a device region of the DMOS device 100 is defined. The isolation regions 12 and a field oxide region 12a for example are a local oxidation of silicon (LOCOS) structure or a shallow trench isolation (STI) structure, the former being shown in the figures. The DMOS device 100 includes an N-type well 14, a gate 13, a drain 15, a source 16, a body region 17, a body electrode 17a, and the field oxide region 12a. The well 14, the drain 15 and the source 16 are formed by lithography process steps and ion implantation process steps, wherein the lithography process step defines the implantation region by a photoresist mask together with a self-alignment effect provided by all or part of the gate 13, and the ion implantation process step implants N-type impurities to the defined region in the form of accelerated ions. The drain 15 and the source 16 are beneath the gate 13 and at different sides thereof respectively. The body region 17 and the body electrode 17a are formed by lithography process steps and ion implantation process steps, wherein the lithography process step defines the implantation region by a photoresist mask together with a self-alignment effect provided by all or part of the gate 13, and the ion implantation process step implants P-type impurities to the defined region in the form of accelerated ions. Part of the gate 13 is above the field oxide region 12a in the DMOS device 100.

The DMOS device is a high voltage device designed for applications requiring higher operation voltages. The DMOS device is a high voltage device designed for applications requiring higher operation voltages. However, if it is required for the DMOS device to be integrated with a low voltage device in one substrate, the DMOS device and the low voltage device should adopt the same manufacturing process steps with the same ion implantation parameters, and the DMOS device is required to be manufactured in a non-epitaxial silicon substrate, and thus the flexibility of the ion implantation parameters and the performance for the DMOS device are limited; as a result, the DMOS device will have a lower breakdown voltage and therefore a limited application range. To increase the breakdown voltage of the DMOS device, the ion implantation parameters should be adjusted, but this will affect the performance of the low voltage device, or an epitaxial silicon substrate should be adopted which increases the cost; either way is not satisfactory.

In view of above, to overcome the drawbacks in the prior art, the present invention proposes a DMOS device and a manufacturing method thereof which increases the breakdown voltage so that the DMOS device may have a broader application range, in which the expensive epitaxial substrate is not required such that the DMOS device can be integrated with a low voltage device by a lower manufacturing cost and the implantation parameters of the low voltage device is unaffected.

### SUMMARY OF THE INVENTION

A first objective of the present invention is to provide a double diffused metal oxide semiconductor (DMOS) device.

A second objective of the present invention is to provide a manufacturing method of a DMOS device.

To achieve the objectives mentioned above, from one perspective, the present invention provides a DMOS device, including: a first conductive type substrate, which has an upper surface; a second conductive type high voltage well, which is formed in the substrate beneath the upper surface; a first conductive type deep buried region, which is formed below the high voltage well in a vertical direction, wherein a gap between the deep buried region and the high voltage well is not less than a predetermined distance; a field oxide region, which is formed on the upper surface, and is located in the high voltage well from top view; a first conductive type body region, which is formed in the substrate beneath the upper surface; a gate, which is formed on the upper surface, wherein part of the gate is above the field oxide region; and a second conductive type source and a second conductive type drain, which are formed beneath the upper surface at two sides of the gate respectively, the drain and the source being separated by the gate and the field oxide region from top view, wherein the drain is located in the high voltage well, and the source is located in the body region.

From another perspective, the present invention provides a manufacturing method of a DMOS device, including: providing a first conductive type substrate, which has an upper surface; forming a second conductive type high voltage well in the substrate beneath the upper surface; forming a first conductive type deep buried region below the high voltage well in a vertical direction, wherein a gap between the deep buried region and the high voltage well is not less than a predetermined distance; forming a field oxide region on the upper surface, wherein the field oxide region is located in the high voltage well from top view; forming a first conductive type body region in the substrate beneath the upper surface; forming a gate on the upper surface, wherein part of the gate is above the field oxide region; and forming a second conductive type source and a second conductive type drain beneath the upper surface at two sides of the gate respectively, the drain and the source being separated by the gate and the field oxide region from top view, wherein the drain is located in the high voltage well, and the source is located in the body region.

In one preferable embodiment, the predetermined distance is 1.5 micro-meters.

In another preferable embodiment, the substrate has a portion including the high voltage well and a portion not including the high voltage well, wherein the body region and the substrate portion not including the high voltage well are separated by the high voltage well, such that the body region and the substrate portion not including the high voltage well are not directly electrically connected.

In another preferable embodiment, the substrate has a portion including the high voltage well and a portion not including the high voltage well, wherein at least part of the body region is directly connected to the substrate portion not including the high voltage well, or is indirectly electrically connected to the substrate portion not including the high voltage well by a first conductive type connecting well, such that the body region and the substrate not including the high voltage well are electrically connected.

In one another preferable embodiment, the deep buried region is located between the source and the drain from top view.

In another preferable embodiment, the deep buried region includes multiple deep buried sub-regions, wherein the deep buried sub-regions are arranged to parallel strips or a rectangular matrix from top view.

The objectives, technical details, features, and effects of the present invention will be better understood with regard to the detailed description of the embodiments below.

### BRIEF DESCRIPTION OF THE DRAWINGS

FIG. 1A shows a cross-section view of a prior art double diffused metal oxide semiconductor (DMOS) device 100.

FIG. 1B shows a 3D (3-dimensional) view of a prior art DMOS device 100.

FIGS. 2A-2D show a first embodiment of the present invention.

FIG. 3 shows a second embodiment of the present invention.

FIG. 4 shows a third embodiment of the present invention.

FIG. 5 shows a fourth embodiment of the present invention.

FIG. 6 shows a fifth embodiment of the present invention.

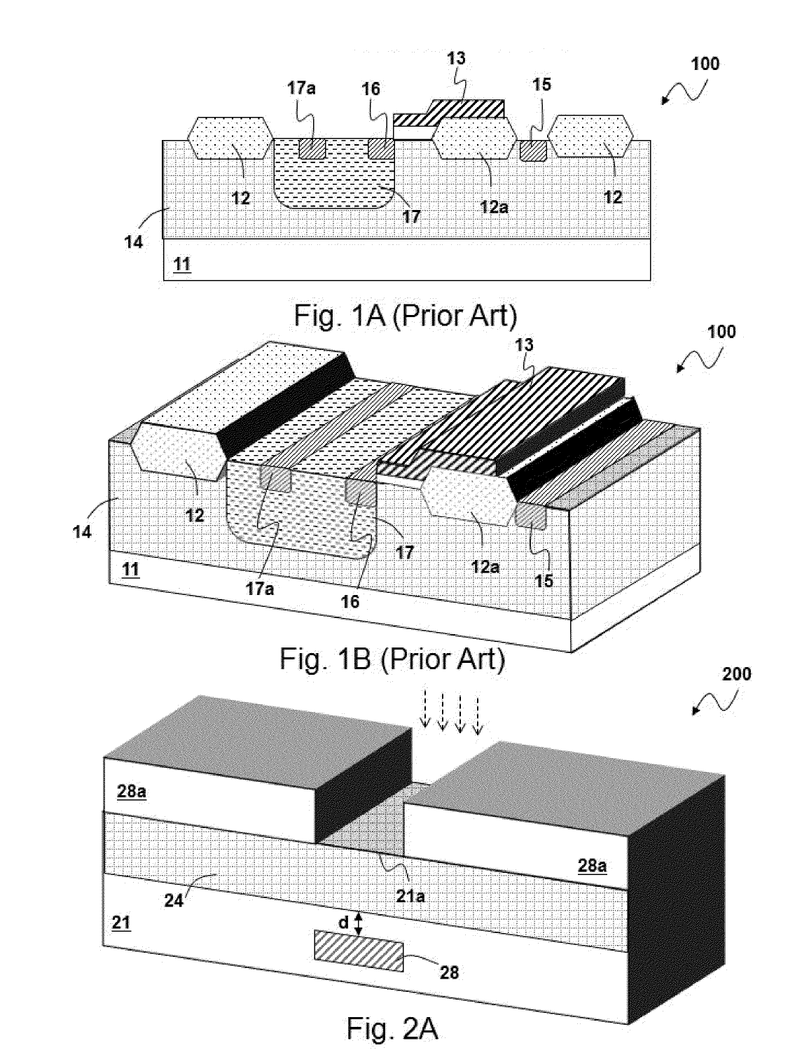

### DESCRIPTION OF THE PREFERRED EMBODIMENTS

The drawings as referred to throughout the description of the present invention are for illustration only, to show the interrelations between the regions and the process steps, but not drawn according to actual scale.

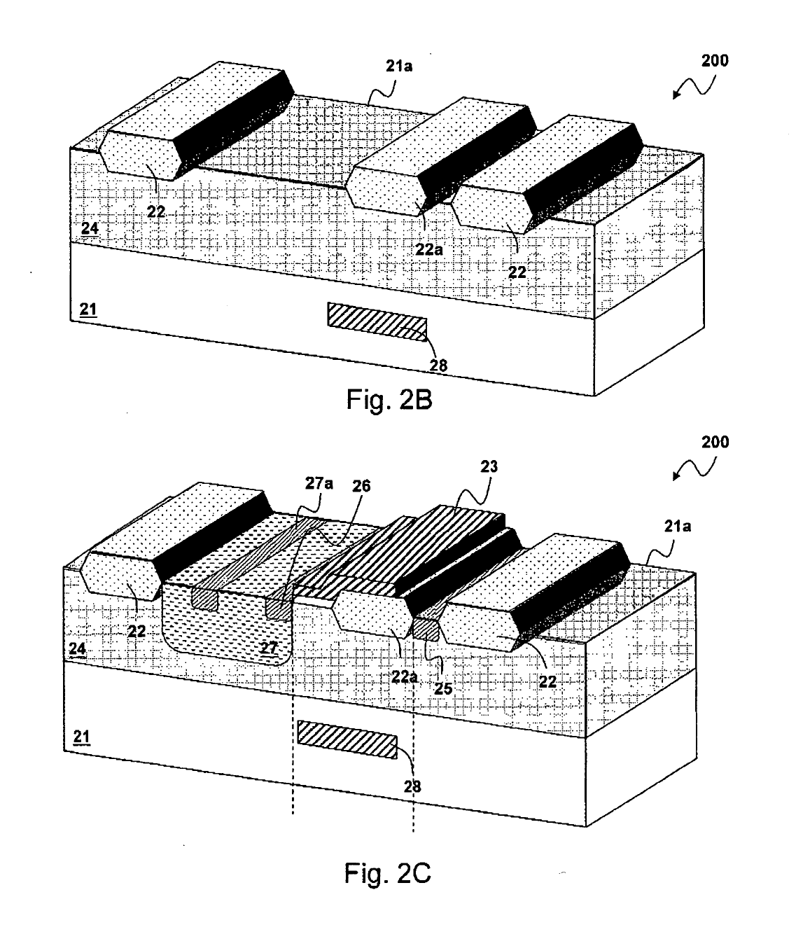

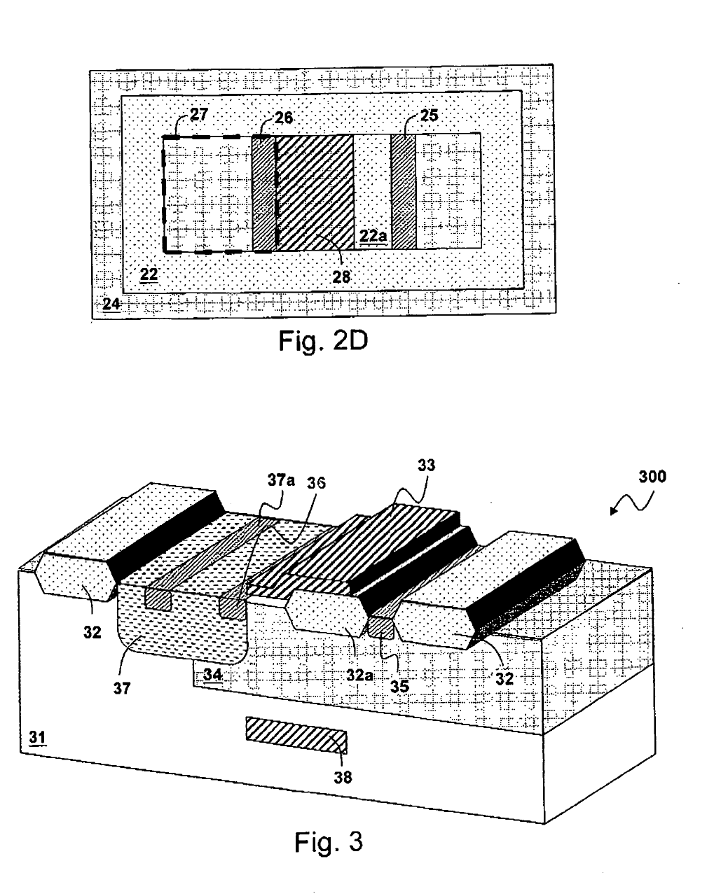

Please refer to FIGS. 2A-2D for a first embodiment according to the present invention, wherein FIGS. 2A-2C are 3D schematic diagrams showing a manufacturing method of an DMOS device 200 according to the present invention, and FIG. 2D is a top view of the DMOS device 200. As shown in FIG. 2A, first, a substrate 21 with an upper surface 21a is provided, wherein the substrate 21 is for example but not limited to a P-type substrate (or an N-type substrate in another embodiment). The substrate 21 for example is a non-epitaxial silicon substrate because it is less expensive, but it can certainly be an epitaxial substrate. Next, an N-type high voltage well 24 is formed in the substrate 21 beneath the upper surface 21a by an ion implantation process step, wherein the ion implantation process step implants N-type impurities to the substrate 21 in the form of accelerated ions. Next, as shown in FIG. 2A, a P-type deep buried region 28 is formed in the substrate 21 below the high voltage well 24 by a lithography process step and an ion implantation process step, wherein the lithography process step defines the implantation region by a photoresist mask, and the ion implantation process step implants P-type impurities to the defined region in the form of accelerated ions as indicated by the dashed arrow lines in the figure. The sequence of the process steps which form the high voltage well 24 and the deep buried region 28 may be switched. Note that, the high voltage well 24 and the deep buried region 28 are formed by different ion implantation process steps, and a gap between the deep buried region 28 and the high voltage well 24 in a vertical direction is not less than a predetermined distance d. The predetermined distance is for example but not limited to 1.5 micro-meters.

Next, as shown in FIG. 2B, isolation regions 22 and a field oxide region 22a are formed on the upper surface 21a. The isolation region 22 and the field oxide region 22a are, for example, a LOCOS or an STI structure (the former being shown in FIGS. 2A-2D). The isolation region 22 and the field oxide region 22a may be formed by for example but not limited to the same process steps. The isolation regions 22 and the field oxide region 22a are located in the high voltage well 24 from the top view of FIG. 2D.

Next, referring to FIG. 2C, a gate 23, a drain 25, a source 26, a body region 27, and a body electrode 27a are formed. As shown in the figure, the gate 23 is formed on the upper surface 21a, and part of the gate 23 is located on the field oxide region 22a. The drain 25 and the source 26 are for example but not limited to N-type, and located beneath the upper surface 21a at two sides of the gate 23. The drain 25 and the source 26 are separated by the gate 23 and the field oxide region 22a from the top view of FIG. 2D. The drain 25 is located in the high voltage well 24, and the source 26 is located in the body region 27 (indicated by the rectangular dashed frame). The body region 27 is for example but not limited to P-type, and formed in the substrate 21 beneath the upper surface 21a.

This embodiment is different from the prior art in that there is a deep buried region 28 formed below the high voltage well 24. This arrangement is advantageous over the prior art in that: First, the DMOS device of the present invention has a relatively higher breakdown voltage. Second, because of the higher breakdown voltage according to the present invention, the impurity concentration of the high voltage well 24 may be increased, such that the conduction resistance of the DMOS device may be decreased.

FIG. 3 shows a second embodiment of the present invention. FIG. 3 is a schematic diagram showing a 3D view of a DMOS device 300 of the present invention. This embodiment is different from the first embodiment. In the first embodiment, the body region 27 is separated from the substrate 21 (more precisely, the portion of the substrate 21 which does not include the high voltage well 24) by the high voltage well 24, such that the body region 27 and the substrate 21 are not directly electrically connected, and the DMOS device 200 may be used as a high side device in a power supply circuit. On the other hand, in this embodiment as shown in FIG. 3, a device region is defined by the isolation region 32, and the DMOS device 300 includes a field oxide region 32a, a gate 33, a high voltage well 34, a drain 35, a source 36, a body region 37, a body electrode 37a, and a deep buried region 38. This embodiment is different from the first embodiment in that, in this embodiment, part of the body region 37 is directly connected to the substrate 31 (more precisely, the portion of the substrate 31 which does not include the high voltage well 34), such that the body region 37 and the portion of the substrate 31 which does not include the high voltage well 34 are electrically connected, and the DMOS device 300 may be used as a low side device in a power supply circuit.

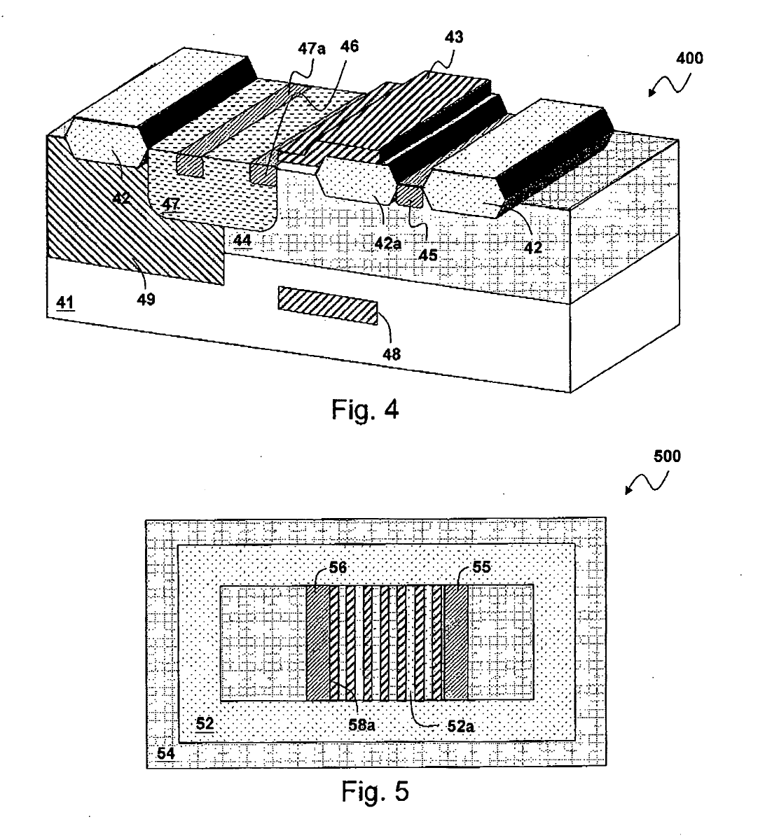

FIG. 4 shows a third embodiment of the present invention. FIG. 4 is a schematic diagram showing a 3D view of a DMOS device 400 of the present invention. As shown in the figure, a device region is defined by the isolation region 42, and the DMOS device 400 includes a field oxide region 42a, a gate 43, a high voltage well 44, a drain 45, a source 46, a body region 47, a body electrode 47a, and a deep buried region 48. This embodiment is different from the second embodiment in that, in this embodiment, part of the body region 47 is connected to the substrate 41 (more precisely, the portion of the substrate 41 which does not include the high voltage well 44) by a P-type connection well 49, such that the body region 47 and the portion of the substrate 41 which does not include the high voltage well 44 are electrically connected, and the DMOS device 400 may be used as a low side device in a power supply circuit.

According the present invention, a depletion region is induced in the drift region from the deep buried region below the high voltage well, especially when the DMOS device is OFF. This depletion region combines with a lateral depletion region generated by the DMOS device in OFF operation, to form a large depletion region which reduces the surface field (RESURF), such that the high level electric field is mitigated when the DMOS is OFF according to the present invention. On the other hand, a properly determined vertical gap between the deep buried region and the high voltage well can increase the junction breakdown voltage, i.e., the electric field which is formed when the DMOS device operates can be decreased, such that the breakdown voltage of the DMOS device can be increased.

Certainly, the sequence of the process steps which form the high voltage well and the deep buried region may be switched, i.e., the high voltage well or the deep buried region maybe formed before the other. Furthermore, the process steps which form the high voltage well or the deep buried region can be performed before or after forming the field oxide region. This indicates that the scope of the present invention is not limited to one single embodiment.

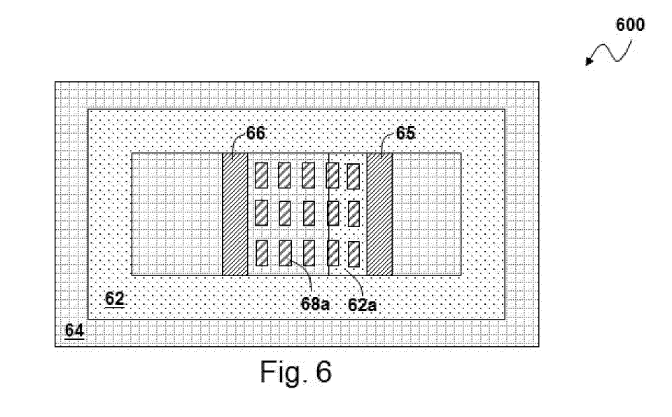

FIGS. 5 and 6 show a fourth embodiment and a fifth embodiment of the present invention respectively. The two embodiments show that the deep buried region may include multiple deep buried sub-regions, wherein the deep buried sub-regions may be arranged as parallel strips or a rectangular matrix from top view. More specifically, FIG. 5 is a schematic diagram showing a top view of a DMOS device 500 of the present invention. The DMOS device 500 includes a high voltage well 54, an isolation region 52, a field oxide region 52a, a drain 55, a source 56, and multiple deep buried sub-regions 58a. FIG. 5 shows that the multiple deep buried sub-regions 58a are arranged in the form of parallel strips, and this arrangement is within the scope of the present invention.

FIG. 6 is a schematic diagram showing a top view of a DMOS device 600 of the present invention. The DMOS device 600 includes a high voltage well 64, an isolation region 62, a field oxide region 62a, a drain 65, a source 66, and multiple deep buried sub-regions 68a. FIG. 6 shows that the multiple deep buried sub-regions 68a are arranged in the form of a rectangular matrix, and this arrangement is also within the scope of the present invention.

The present invention has been described in considerable detail with reference to certain preferred embodiments thereof. It should be understood that the description is for illustrative purpose, not for limiting the scope of the present invention. Those skilled in this art can readily conceive variations and modifications within the spirit of the present invention. For example, other process steps or structures which do not affect the primary characteristic of the device, such as a threshold voltage adjustment region, etc., can be added. For another example, the lithography step described in the above can be replaced by electron beam lithography, X-ray lithography, etc. For another example, the shape of the DMOS device from top view according to the present invention is not limited to rectangular; it maybe circular or of any other shape. In view of the foregoing, the spirit of the present invention should cover all such and other modifications and variations, which should be interpreted to fall within the scope of the following claims and their equivalents.

1. A double diffused metal oxide semiconductor (DMOS) device, comprising:
a first conductive type substrate, which has an upper surface;
a second conductive type high voltage well, which is formed in the substrate beneath the upper surface;
a first conductive type deep buried region, which is formed below the high voltage well in a vertical direction, wherein a gap between the deep buried region and the high voltage well is not less than a predetermined distance;
a field oxide region, which is formed on the upper surface, and is located in the high voltage well from top view;
a first conductive type body region, which is formed in the substrate beneath the upper surface;
a gate, which is formed on the upper surface, wherein part of the gate is above the field oxide region; and
a second conductive type source and a second conductive type drain, which are formed beneath the upper surface at two sides of the gate respectively, the drain and the source being separated by the gate and the field oxide region from top view, wherein the drain is located in the high voltage well, and the source is located in the body region;
wherein when the DMOS device is OFF, a first depletion region is formed between the deep buried region and the high voltage well, and a second depletion region is formed in the high voltage well, wherein the first depletion region connects with the second deletion region.

2. The DMOS device of claim 1, wherein the predetermined distance is 1.5 micro-meters.

3. The DMOS device of claim 1, wherein the substrate has a portion including the high voltage well and a portion not including the high voltage well, and wherein the body region and the substrate portion not including the high voltage well are separated by the high voltage well, such that the body region and the substrate portion not including the high voltage well are not directly electrically connected.

4. The DMOS device of claim 1, wherein the substrate has a portion including the high voltage well and a portion not including the high voltage well, and wherein at least part of the body region is directly connected to the substrate portion not including the high voltage well, or is indirectly electrically connected to the substrate portion not including the high voltage well by a first conductive type connecting well, such that the body region and the substrate not including the high voltage well are electrically connected.

5. The DMOS device of claim 1, wherein the deep buried region is located between the source and the drain from top view.

6. The DMOS device of claim 1, wherein the deep buried region includes a plurality of deep buried sub-regions, wherein the deep buried sub-regions are arranged in a form of parallel strips or a rectangular matrix from top view.

7. A manufacturing method of a double diffused metal oxide semiconductor (DMOS) device, comprising:
providing a first conductive type substrate, which has an upper surface;
forming a second conductive type high voltage well in the substrate beneath the upper surface;
forming a first conductive type deep buried region below the high voltage well in a vertical direction, wherein a gap between the deep buried region and the high voltage well is not less than a predetermined distance;
forming a field oxide region on the upper surface, wherein the field oxide region is located in the high voltage well from top view;
forming a first conductive type body region in the substrate beneath the upper surface;
forming a gate on the upper surface, wherein part of the gate is above the field oxide region; and
forming a second conductive type source and a second conductive type drain beneath the upper surface at two sides of the gate respectively, the drain and the source being separated by the gate and the field oxide region from top view, wherein the drain is located in the high voltage well, and the source is located in the body region;
wherein when the DMOS device is OFF, a first depletion region is formed between the deep buried region and the high voltage well, and a second depletion region is formed in the high voltage well, wherein the first depletion region connects with the second depletion region.

8. The manufacturing method of claim 7, wherein the predetermined distance is 1.5 micro-meters.

9. The manufacturing method of claim 7, wherein the substrate has a portion including the high voltage well and a portion not including the high voltage well, and wherein the body region and the substrate portion not including the high voltage well are separated by the high voltage well, such that the body region and the substrate portion not including the high voltage well are not directly electrically connected.

10. The manufacturing method of claim 7, wherein the substrate has a portion including the high voltage well and a portion not including the high voltage well, and wherein at least part of the body region is directly connected to the substrate portion not including the high voltage well, or is indirectly electrically connected to the substrate portion not including the high voltage well by a first conductive type connecting well, such that the body region and the substrate not including the high voltage well are electrically connected.

11. The manufacturing method of claim 7, wherein the deep buried region is located between the source and the drain from top view.

12. The manufacturing method of claim 7, wherein the deep buried region includes a plurality of deep buried sub-regions, wherein the deep buried sub-regions are arranged in a form of parallel strips or a rectangular matrix from top view.
